(19) United States
(12) Patent Application Publication
(10) Pub. No.: US 2009/0084444 A1
(43) Pub. Date: Apr. 2, 2009

(54) Photovoltaic devices based on a novel block copolymer

(76) Inventor: Sam-Shajing Sun, Chesapeake, VA (US)

Correspondence Address: WILLIAMS MULLEN, 222 CENTRAL PARK AVENUE, SUITE 1700, VIRGINIA BEACH, VA, 23462, US

(21) Appl. No.: 12/214,050

(22) Filed: Jun. 16, 2008

Related U.S. Application Data
(62) Division of application No. 10/714,230, filed on Nov. 14, 2003.
(60) Provisional application No. 60/426,108, filed on Nov. 14, 2002.

(51) Int. Cl. H01L 31/00

(52) U.S. Cl. 136/263

(57) ABSTRACT

A -donor(D)-bridge(B)-acceptor(A)-bridge(B)-type block copolymer system, where donor (D) is an organic conjugated donor (p-type) block, acceptor (A) is an organic conjugated acceptor (n-type) block, and bridge (B) is a non-conjugated and flexible chain, has been designed and preliminarily tested for potential lightweight, flexible shape, cost-effective and high efficiency “plastic” thin film solar cell or photo detector applications. A ‘tertiary supramolecular nanophase separated structure” derived from this -DBAB-block copolymer improves opto-electronic (photovoltaic) power conversion efficiency significantly in comparison to all existing reported organic or polymeric donor/acceptor binary photovoltaic systems due to the reduction of “exciton loss,” the “carrier loss,” as well as the “photon loss” via three-dimensional space (morphology) and energy level optimizations.

### CROSS-REFERENCE TO RELATED APPLICATION

This application is a divisional of U.S. application Ser. No. 10/714,230, filed on Nov. 14, 2003, titled Photovoltaic Devices Based on a Novel Block Copolymer, which claims the benefit of priority from U.S. Provisional Application Ser. No. 60/426,108, filed Nov. 14, 2002, both of which are hereby incorporated by reference.

### STATEMENT REGARDING GOVERNMENT SUPPORT

This invention was made in part with government support under Grant No. NAG3-2289 awarded by NASA, F-49620-01-1-0485 and F-49620-02-1-0062 awarded by the Air Force Office of Scientific Research. The government has certain rights in this invention.

### BACKGROUND OF THE INVENTION

1. Field of the Invention

The present invention relates generally to the field of photovoltaic or photoelectric materials and devices. More particularly, this invention relates to fabricating high efficiency, lightweight, cost effective, and flexible shaped “plastic” thin film photo detectors and solar cells employing the donor-bridge-acceptor-bridge, or similar type, block copolymers.

2. Description of the Related Art

Photovoltaic (PV) or photoelectric (PE) is a process where an open circuit voltage or a short-circuit electric current is generated in a media (materials or devices) as a result of light radiation. PV or PE devices therefore are able to convert solar energy directly into electric energy, or convert light signals into electrical signals. They are, therefore, very useful for renewable and clean energy generation and optical signal processing.

Before discussing organic photovoltaics, we shall briefly compare a classic inorganic solar cell (such as the “Fritts Cell” reported in 1885 and described by J. Perlin, From Space to Earth—The Story of Solar Electricity, AATEC Publications, Ann Arbor, Mich., 1999) versus an organic solar cell (such as the “Tang Cell” described by C. Tang in U.S. Pat. No. 4,164,431 in 1979 and in “Two-layer organic photovoltaic cell,” Appl. Phys. Lett., 48, 183 (1986)).

As shown in FIG. 1, the “Fritts Cell” was composed of a semiconducting selenium thin layer sandwiched between two different thin layer metal electrodes, one gold layer acting as a large work function electrode (LWFE) and the other metal layer acting as a small work function electrode (SWFE). In this cell, when an energy matched photon strikes the selenium, a free electron is generated in the connection band (CB), and a free hole was left in the valence band (VB) as shown in FIG. 2. The free electron and hole (also called “charged carriers” or simply “carriers”) can easily be separated from each other, even by thermal energy at room temperature, and they can diffuse to the respective and opposite electrodes under a field created by the two different work function metal electrodes.

In contrast, in the first organic solar cell (the “Tang Cell”), as shown in FIG. 3, when an energy matched photon strikes an organic unit, it only generates a neutral and tightly bonded electron-hole pair called an “exciton.” It is believed that the neutral exciton can diffuse randomly in any direction, even under a static electric field. However, if two different organic materials (or “phases”) are present and in direct contact with each other, one material has a higher set of the Lowest Unoccupied Molecular Orbital/Highest Occupied Molecular Orbital (“LUMO/HOMO”) levels, called a “donor,” and the other material has a lower set of LUMO/HOMO levels, called an “acceptor,” as shown in FIG. 4, then, when a photo-generated exciton diffuses and reaches an interface of the donor and acceptor, if the exciton is at the donor side, the photo-generated electron at the donor LUMO will transfer into the acceptor LUMO. If the exciton is at the acceptor side, the photo-generated hole at the acceptor HOMO will jump into the donor HOMO (corresponding to an electron back transfer). Thus, a neutral exciton now becomes a free electron (at the acceptor LUMO) and a free hole (at the donor HOMO). Now the freed electrons and holes can diffuse to the respective electrodes in two separate phases. Thus, a donor/acceptor binary system appears to be critical for organic photovoltaics. For organic solar cells, the power conversion efficiencies are limited by at least the following steps:
1) Photon absorption or exciton generation;
2) Exciton diffusion to donor/acceptor interfaces;
3) Exciton separation or charged carrier generation;
4) Carrier transportation (diffusion) to respective electrodes; and
5) Carrier collection by the electrodes.

For all currently reported organic or polymeric photovoltaic devices, none of the above-mentioned five steps have been optimized. It is, therefore, not surprising that the power conversion efficiency of those reported organic or polymeric solar cells is very low in comparison to typical inorganic solar cells.

### Photon Absorption or Exciton Generation

In this first step of organic photovoltaics, a critical requirement is that the material's optical excitation energy gap (“optical gap”) must be equal to or smaller than the incident photon energy. In organic systems, this gap is the energy gap between the Highest Occupied Molecular Orbital (“HOMO”) and the Lowest Unoccupied Molecular Orbital (“LUMO”). For molecules containing double or triple bonds (π orbitals), HOMO typically refers to the highest occupied π orbital(s) (such as π bonding orbitals at ground state), and LUMO refers to the unoccupied π orbitals (such as π* anti-bonding orbitals at ground state). For molecules containing only single bonds (a orbitals), HOMO typically refers to the highest occupied a orbital(s) (such as σ bonding orbitals at ground state) and LUMO refers to the unoccupied a orbitals (such as σ* anti-bonding orbitals at ground state). Since an organic HOMO to LUMO excitation only generates an exciton instead of a free electron and hole, “optical gap” is commonly used here instead of the traditional electronic “band gap” that typically refers to the energy gap between the free holes at valence band (VB) and the free electrons at conduction band (CB) in a semiconducting inorganic material (FIG. 2). In organic materials, the relationship of “optical gap (E_{go})” versus “electronic gap (E_{ge})” can be expressed as E_{go}=E_{ge}+E_{eb}, where E_{eb} is called exciton binding energy. E_{go} values can be conveniently obtained from materials UV-VIS absorption spectra. E_{ge} values may be estimated by electrochemical analysis such as cyclic voltammetry (CV), as described by S. Janietz, et al., “Electrochemical determination of the ionization potential and electron affinity of poly(9,9)-dioctylfluorene,” Appl. Phy. Lett., 73, 2453-2455 (1998), incorporated herein by reference. For a widely used conjugated and semiconducting polymer poly-p-phenylenevinylenes, or PPV, the exciton binding energy is about 0.4-0.5 eV, as quoted by T. Stubinger, et al., “Exciton diffusion and optical interference in organic donor-acceptor photovoltaic cells,” J. Appl. Phys., 90(7), 3632 (2001), incorporated herein by reference. For solar cell applications, since solar light radiation spans a wide range yet with largest photo-flux (at 1.5 air mass) in the range of 600-900 nm (1.3-2.0 eV), as quoted by C. Brabec, et al., in Organic Photovoltaics: Concepts and Realization, Springer, Berlin, 2003, incorporated herein by reference; therefore, the ideal optical band gap of an organic solar cell should match this radiation range. Unfortunately, several widely used conjugated semiconducting polymers all have optical gaps higher than 2.0 eV, as cited in T. A. Skotheim, et al., Handbook of Conducting Polymers, 2d ed., Marcel Dekker, New York, 1998. For instance, poly-p-phenylenevinylene (PPV) has a typical optical gap of about 2.5 eV, well above the maximum solar photon flux range. This is why the photon absorption (exciton generation) for PPV-based solar cells is far from optimal. This “photon loss” problem is in fact very common in almost all of the reported organic photovoltaic materials and devices. However, one advantage of organic materials is their versatility to fine-tine the energy levels via molecular design and synthesis; therefore, there is still ample room for improvement. A number of recent studies on the developments of low band gap conjugated polymers are such examples. For instance, N. Sariciftci, et al., described “A Low-Bandgap Semiconducting Polymer for Photovoltaic Devices and Infrared Emitting Diodes,” Adv. Funct. Mater., 12, 709-712 (2002), incorporated herein by reference.

### Exciton Diffusion

Once an exciton (tightly bonded electron-hole pair) is photo-generated, it typically will decay (radiatively or non-radiatively) back to ground state at nanoseconds or longer time frames. Alternatively, in the solid state, some excitons may be trapped in solid defect, or “doping,” sites. Both of these situations would contribute to the “exciton loss.” However, even within its short lifetime, an exciton on a conjugated polymer chain can diffuse to a remote site via inter-chain and intra-chain interactions, or coupling. The interaction can be either via hopping or via energy transfer (for a single exciton, for instance, it can be a Förster energy transfer process), as described by J. Schwartz, et al, in “Control of Energy Transfer in Oriented Conjugated Polymer-Mesoporous Silica Composites,” Science, 288, 652 (2000), incorporated herein by reference. For conjugated organic materials, the average exciton diffusion length (limited by the exciton lifetime and the material's morphology) is typically in the range of 10-100 nm, as cited by T. Stubinger, et al. For instance, the average diffusion length for PPV is around 10 nm n. This means that the best way to minimize the “exciton loss” would be to build a material with a defect-free tertiary nanostructure, such that an exciton generated at any site of the material can reach a donor/acceptor interface in all directions within the average exciton diffusion length. One limitation of the “Tang Cell” is that, if the donor or acceptor layer is thicker than the average exciton diffusion length (10-100 nm), then “exciton loss” would be a problem. However, if the photovoltaic active layer thickness is well below the excitation photon wavelength (600-900 nm in the case of a solar cell), then “photon loss” would become a problem. Most importantly, the double layer structure has a relatively small donor/acceptor interface in comparison to blends.

### Exciton Separation/Carrier Generation

Once an exciton diffuses to a donor/acceptor interface, or an exciton is generated near the interface, the interface potential field generated by the donor/acceptor HOMO/LUMO differences would then separate the exciton into a free electron at acceptor LUMO and a free hole at donor HOMO, provided such field is sufficient enough to overcome the exciton binding energy (E_{eb}). This electron transfer process is also called “photodoping,” as it is a photo-induced reduction-oxidation or “Redox” process between the donor and the acceptor. On the other hand, the LUMO/HOMO pair difference between the donor and acceptor should not be too large, as that will not only reduce the open circuit voltage (V_{oc}) that is closely related to the donor HOMO and acceptor LUMO, as reported by C. J. Brabec, et al., in “Origin of the open circuit voltage of plastic solar cells,” Adv. Funct. Mater., 11, 374-380 (2001), incorporated herein by reference. It may also incur ground state electron transfer from the donor HOMO directly to the acceptor LUMO (“chemical doping”). Therefore, an ideal LUMO/HOMO pair difference between the donor and the acceptor appears to be around the exciton binding energy (E_{eb}). For a PPV donor and fullerene acceptor binary system, it has been found that the photo-induced electron transfer process at the PPV/fullerene interface occurs at sub-picoseconds, as reported by A. J. Heeger, et al., in “Subpicosecond photoinduced electron transfer from conjugated polymers to functionalized fullerenes,” J. Chem. Phys., 104, 4267-4273 (1996), incorporated herein by reference, about three orders of magnitude faster than the average PPV exciton decay. This means opto-electronic quantum efficiency at such interface is almost unity, and a high efficiency organic photovoltaic system is quite possible.

### Carrier Diffusion to the Electrodes

Once the carriers (free electrons or holes) are generated, holes need to diffuse toward the large work function electrode (LWFE), and electrons need to diffuse toward the small work function electrode (SWFE). The driving force here for the carriers is the relatively weak field generated by the two different work function electrodes. In addition, another driving force called “chemical potential” may also play a role, as described by B. Gregg in “Excitonic Solar Cells,” J. Phys. Chem. B., 107, 4688-4698 (2003), incorporated herein by reference. “Chemical potential” driving force can be interpreted simply as a density-driven force, i.e., particles tend to diffuse from a higher density domain to a lower density domain. In an organic donor/acceptor binary photovoltaic cell, for instance, high density electrons at the acceptor LUMO near the donor/acceptor interface tend to diffuse to a lower electron density region within the acceptor phase, and high density holes at the donor HOMO near the donor/acceptor interface tend to diffuse to the lower hole density region within the donor phase. For instance, in the “Tang Cell,” as shown in FIG. 3, at the donor/acceptor (D/A) interface, once an exciton is separated into a free electron in the acceptor side and a free hole in the donor side, the electron will be “pushed” away from the interface toward the negative electrode by both the “chemical potential” and by the field formed from the two electrodes. The holes will be “pushed” toward the positive electrode by the same forces but in the opposite directions. With this chemical potential force, even if the two electrodes are the same, asymmetric photovoltage or photocurrent could still be achieved (i.e., the donor side would be positive and the acceptor side negative). However, right after electron-hole separation at the interface, they can also recombine, though at a much slower rate of micro- to milliseconds. Additionally, the diffusion of electrons and holes to their respective electrodes is not really smooth due to poor morphology of most currently reported organic photovoltaic systems. If all LUMO and HOMO orbitals are well-aligned and overlapped with each other in both donor and acceptor phases, like in molecularly self-assembled thin films, then the carriers will be able to diffuse much more smoothly in a “band” type of pathway toward their respective electrodes. As a matter of fact, it has been demonstrated that molecular self-assembly in polythiophene enhances carrier mobility significantly, as described by Z. Bao, et al., in “Soluble and processable regioregular poly(3-hexylthiophene) for thin file-effect transistor applications with high mobility,” Appl. Phys. Lett., 69, 4108 (1996), incorporated herein by reference. Currently, carrier “hopping” and “tunneling” are believed to be the dominant conductivity mechanism for most reported organic photovoltaic systems, and the “carrier loss” is believed to be a key factor for the low efficiency of organic photovoltaic materials and devices.

### Carrier Collection at the Electrodes

It has been proposed by G. Yu, et al., in “Polymer Photovoltaic Cells: Enhanced Efficiencies via a Network of Internal Donor-Acceptor Heterojunctions,” Science, 270, 1789 (1995), incorporated herein by reference, that when the acceptor LUMO level matches the Fermi level of the small work function electrode, and the donor HOMO matches the Fermi level of the large work function electrode, a desired “Ohmic” contact might be established for efficient carrier collection at the electrodes. So far, there are no organic photovoltaic systems that have realized this desired “Ohmic” contact due to the availability and limitations of materials and electrodes involved. There were a number of studies, however, focusing on the open circuit voltage (V_{oc}) dependence on materials LUMO/HOMO levels, electrode Fermi levels, and chemical potential gradients, as stated above. The carrier collection mechanisms at electrodes are relatively less studied and less understood. It is believed that the carrier collection loss at the electrodes is also a major contributing factor to the low efficiency of current organic solar cells.

Though there are a number of attempts to design or fabricate “bicontinuous” nanostructures for photovoltaic applications, such as those proposed by Salafsky in U.S. Pat. No. 6,239,355 B1, by A. Alivisatos, et al., in “Hybrid Nanorod-Polymer Solar Cells,” Science, 295, 2425 (2002), incorporated herein by reference, and by A. Cravino, et al., in “Electrochemical and Photophysical Properties of a Novel Polythophene with Pendant Fulleropyrrolidine Moieties: Toward ‘Double Cable’ Polymers for Optoelectronic Devices,” J. Phys. Chem., B, 106, 70 (2002), incorporated herein by reference. Unfortunately, nanoparticles, nanorods, or fullerenes cannot form a continuous pathway for charged carriers (such as electrons) to transport smoothly.

The block copolymer approach to photovoltaic functions offers some intrinsic advantages that could hardly be achieved in composite bilayer or blend devices. Block copolymer melts are known to exhibit behavior similar to conventional amphiphilic systems such as lipid-water mixtures, soap, and surfactant solutions, as summarized by M. Lazzari, et al., in “Block Copolymers for Nanomaterial Fabrication,” Adv. Mater. 15, 1584-1594 (2003), incorporated herein by reference. The connection between distinct blocks imposes severe constraints on possible equilibrium states, which results in unique supra-molecular nanodomain structures such as lamellae (LAM), hexagonally (HEX) packed cylinders or columns, spheres packed on a body-centered cubic lattice (BCC), hexagonally perforated layers (HPL), and at least two bicontinuous phases: the ordered bicontinuous double diamond phase (OBDD) and the gyroid phase. The morphology of block copolymers is affected by composition, block size, temperature and other factors. Though a MEH-PPV/polystyrene (with partial C₆₀ derivatization on polystyrene block) donor/acceptor diblock copolymer system has recently been reported by G. Hadziionnou, et al., in “Supramolecular self-assembly and opto-electronic properties of semiconducting block copolymers,” Polymer, 42, 9097 (2001), incorporated herein by reference, and phase separation between the two blocks was indeed observed. The polystyrene/C₆₀ acceptor block is, however, not a conjugated chain system; the poor electron mobility, or “carrier loss” problem in the polystyrene phase, is still not solved. On the other hand, when a conjugated donor block was connected directly with a conjugated acceptor block to form a p-n type conjugated diblock copolymer, as reported by S. A. Jenekhe, et al., in “Block Conjugated Copolymers: Toward Quantum-Well Nanostructures for Exploring Spatial Confinement Effects on Electronic, Optoelectronic, and Optical Phenomena,” Macromolecules, 29, 6189 (1996), incorporated herein by reference, though energy transfers from higher optical gap block to lower optical gap block were observed, no charge separated states were identified; therefore, it is not usable for photovoltaic functions.

Accordingly, it is an object of the present invention to provide an improved system for converting solar energy into electric energy.

Another object of the present invention is to provide an improved system for renewable and clean energy generation.

Another object of the present invention is to provide an improved, high efficiency system.

Another object of the present invention is to provide a system for converting solar energy into electric energy which reduces or eliminates losses found in previous systems.

Yet another object of the present invention is to provide an improved, high efficiency system which is light weight, flexible in shape and cost effective.

Finally, it is an object of the present invention to accomplish the foregoing objectives in a simple and cost-effective manner.

### SUMMARY OF THE INVENTION

An improved organic photovoltaic device is provided which consists of a conjugated donor block and a conjugated acceptor block joined together by a non-conjugated bridge. In the preferred embodiment, the conjugated donor block has a higher highest occupied molecular orbital and a higher lowest unoccupied molecular orbital than the conjugated acceptor block. The non-conjugated bridge has a highest occupied molecular orbital which is lower than the highest occupied molecular orbital of the conjugated donor block and the conjugated acceptor block and a lowest unoccupied molecular orbital which is higher than the lowest unoccupied molecular orbital of the conjugated donor block and the conjugated acceptor block. The non-conjugated bridge is preferably flexible and formed such that it is able to bend 180°. A plurality of conjugated donor blocks and conjugated acceptor blocks may be alternately joined by non-conjugated bridges and stacked or formed in to columns. In the column format, the columns are sandwiched by a positive electrode and a negative electrode. In a further preferred embodiment, a thin donor layer is formed between the positive electrode and the columns and a thin acceptor layer is formed between the negative electrode and the columns.

The device is preferably formed a follows. Photovoltaic block copolymer samples are synthesized and then dissolved in a solvent which will preferably dry conveniently. Preferably, the copolymer samples are synthesized by individually synthesizing conjugated donor chains, conjugated acceptor chains and non-conjugated bridge chains, combining the non-conjugated bridge chains with either the conjugated donor chains or the conjugated acceptor chains to form a plurality of bridge-donor-bridge units or bridge-acceptor-bridge units, and combining the formed units with the remaining complimentary conjugated chains. The mixture is then filtered. A film of the filtered mixture is formed on a prepared surface, preferably conducting glass, by spin coating or drop drying or other appropriate method and the solvent is removed by heating, vacuum or a combination. To achieve the desired chain direction, the structure may then be heated and exposed to a magnetic, electrical or optical force.

### DESCRIPTION OF THE DRAWINGS

FIG. 1 shows a simple prior art inorganic semiconductor solar cell, or “Fritts Cell.”

FIG. 2 illustrates energy levels and photo-electric processes in the “Fritts Cell.”

FIG. 3 shows a simple prior art organic solar cell, or “Tang Cell.”

FIG. 4 illustrates energy levels and intermolecular photo-electric processes in the “Tang Cell.”

FIG. 5 shows the “primary structure” of the invented block copolymer.

FIG. 6 illustrates energy levels of the invented -DBAB-type block copolymer system.

FIG. 7 shows an example of the “secondary structure” of the invented block copolymer thin film.

FIG. 8 shows an example of the “tertiary structure” of the invented block copolymer thin film.

FIG. 9 shows a first example photovoltaic cell using the invented block copolymer.

FIG. 10 shows a second example photovoltaic cell using the invented block copolymer.

FIG. 11 shows structures and key synthetic schemes of a specific -DBA-block copolymer already tested.

FIG. 12 shows a diagram of a -DBAB-type photovoltaic cell already fabricated and tested.

FIG. 13 shows the photo current test results for one fabricated -DBAB-block copolymer photovoltaic cell.

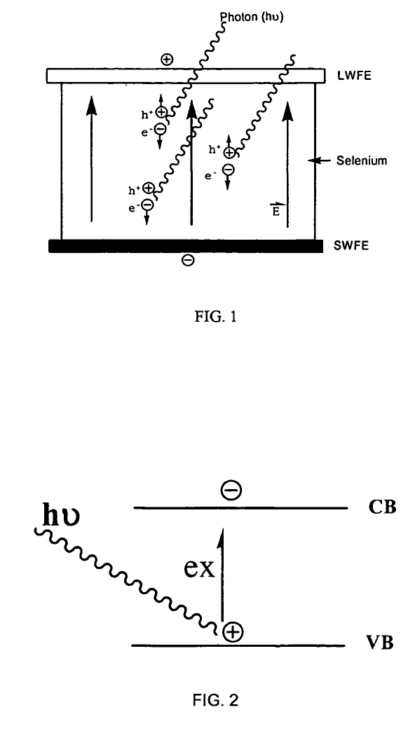

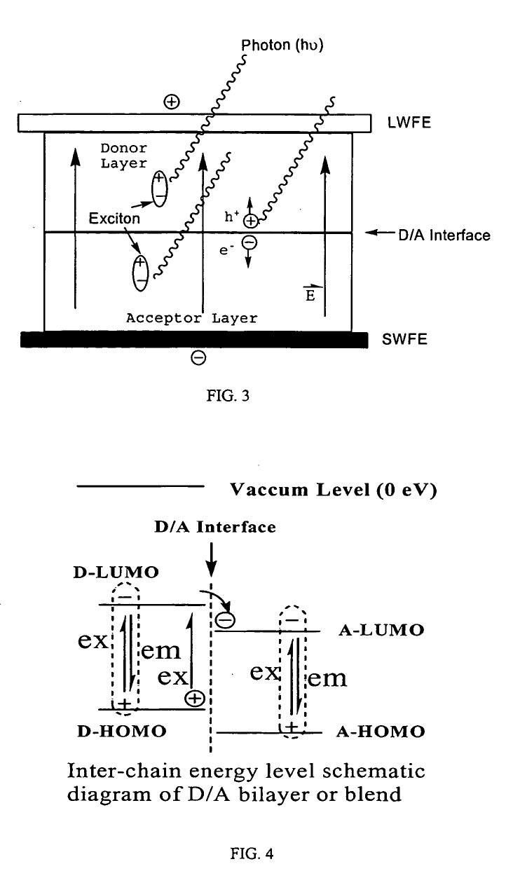

### DETAILED DESCRIPTION OF THE PREFERRED EMBODIMENT

The following detailed description is of the best presently contemplated modes of carrying out the invention. This description is not to be taken in a limiting sense, but is made merely for the purpose of illustrating general principles of embodiments of the invention.

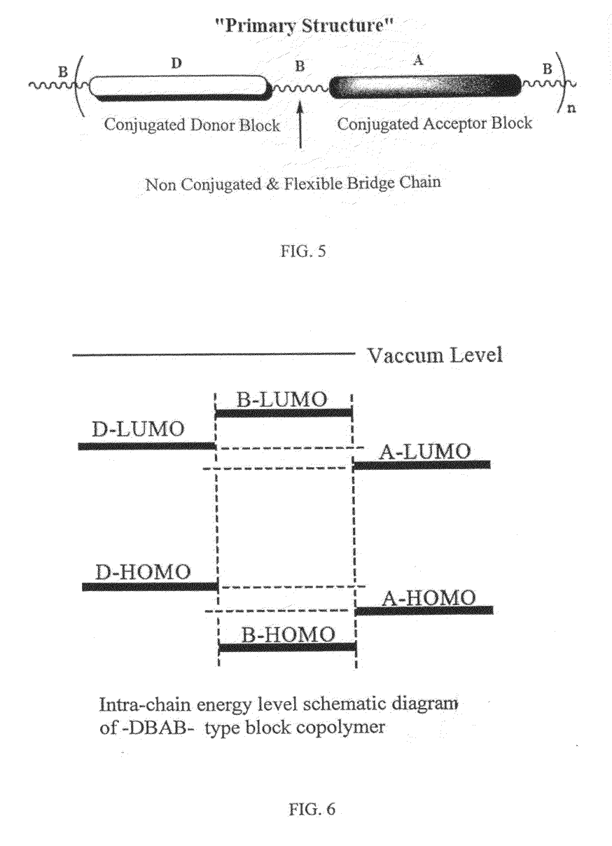

In order to address the loss issues discussed above, a photovoltaic device based on a -DBAB-type of block copolymer system, as shown in FIG. 5, is provided. The invention is further described in “Design of a Block Copolymer Solar Cell,” Sol. Energy Mater. Sol. Cells, 79, 257-264 (2003), incorporated herein by reference. In this novel block copolymer system, D is a π electron conjugated donor block with an optical gap matching the desired photon flux and energy (i.e., solar spectra and maximum photon flux range in case of solar cells, or optical signal wavelength in case of photo detectors), A is a conjugated acceptor block, also with an optical gap matching the desired photon energy and maximum flux, and the energy level differences between the donor and acceptor blocks are such that it is just sufficient enough to overcome the exciton binding energy. B is a non-conjugated and flexible bridge unit with a much higher band gap than both the donor and the acceptor blocks, as shown in FIG. 6. Since both the donor and acceptor blocks are π electron conjugated chains, good carrier transport in both donor and acceptor phases now becomes feasible.

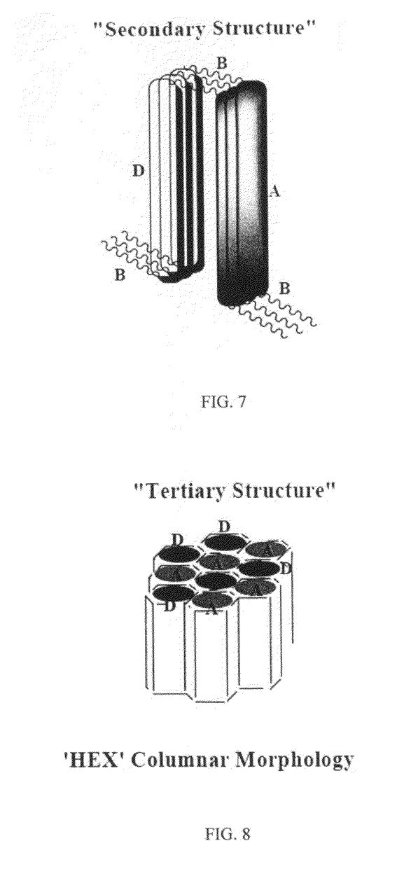

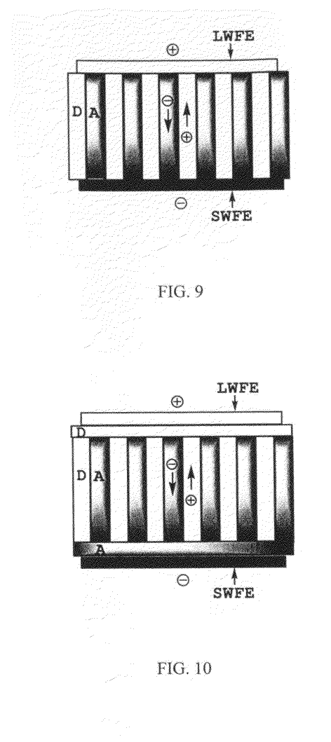

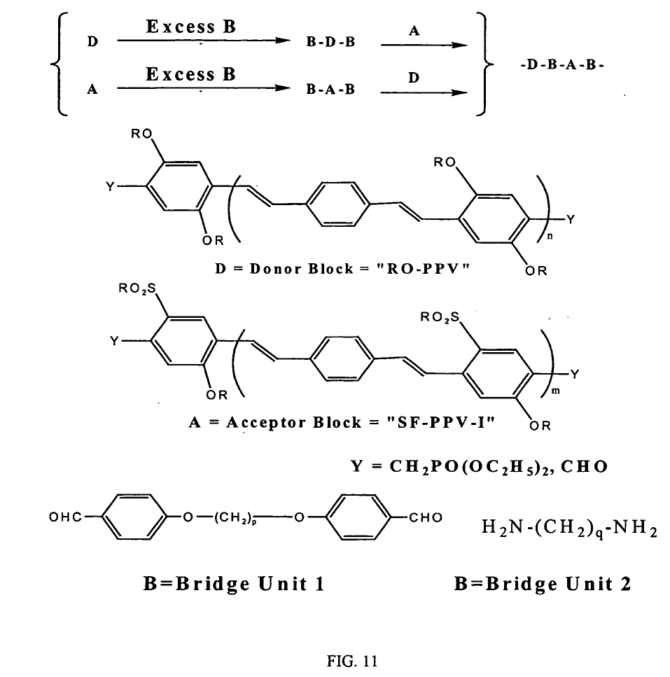

A non-conjugated and flexible bridge unit (such as an aliphatic chain containing only σ bonds) is important because: (1) a non-conjugated bridge unit will hinder the intra-chain electron-hole recombination due to the partially insulating nature of organic single bond chains; (2) intra- or inter-molecular energy and electron transfer or electron-hole separation can still proceed effectively through σ bonds or through space under photo-excitations, as shown by M. R. Wasielewski, et al, in “Factoring through-space and through-bond contributions to rates of photoinduced electron transfer in donor-spacer-acceptor molecules,” J. Photochem. & Photobiol. (A), 102(1), 71 (1997), incorporated herein by reference; (3) the flexibility of the flexible bridge unit would also enable the rigid donor and acceptor conjugated blocks more easily to phase separate and self-assemble and be less susceptible to conjugation distortion. This -DBAB-backbone can be called the “primary structure” (FIG. 5). Additionally, the substituents of donor and acceptor blocks can be fine-tuned in such a way that one could introduce forces similar to those exhibited in the derivatized regioselective polythiophenes, as shown by Z. Bao, et al., to induce the π orbital closely stacked and ordered “secondary structure” as one example shown in FIG. 7. The π orbital stacked “secondary structure” has been found to exhibit dramatically enhanced carrier mobility due to improved π orbital overlapping. Finally, through the adjustment of block size, block derivatization, and multi-layer processing protocols, a “tertiary structure,” as shown in FIG. 8, where a “HEX” or columnar-type block copolymer morphology is vertically sandwiched between a larger work function positive electrode (e.g., ITO-coated transparent sheet or glass) and a smaller work force function negative electrode e.g., aluminum or calcium) can be realized, as shown in FIG. 9. Even better, a thin donor layer can be sandwiched between the LWFE and block copolymer layer and a thin acceptor layer can be sandwiched between the SWFE and block copolymer layer, as shown in FIG. 10. This second device structure would enable a desired asymmetry and favorable chemical potential gradient for asymmetric (selective) carrier diffusion and collection under even the two same electrodes. Since the diameter of each donor or acceptor block column can be conveniently controlled via synthesis and processing to be within the typical organic exciton diffusion range of 10-100 nm, every photo-induced exciton will be in convenient reach of a donor/acceptor interface. At the same time, photo-generated carriers can diffuse more smoothly to their respective electrodes via a truly “bicontinuous” or “channeled” block copolymer “HEX” or related columnar morphology. While the increased donor and acceptor interface size and phase morphology will dramatically minimize the exciton and carrier losses, it nevertheless may also increase the carrier recombination at the same interfaces. However, this charge recombination typically occurs on the microseconds or slower timescale, and this is in contrast to the ultra-fast femto-second charge separation rate at the same interface. Therefore, the charge carrier recombination does not appear to be of a major concern for solar cell applications where the radiation is continuous. The charge recombination may also be minimized by fine-tuning the energy levels of the materials, as the energy level differences also affect charge recombination rate. This block copolymer photovoltaic device may, to a certain degree, minimize a dye-sensitized solar cell (DSSC), as reported by M. Graetzel, et al., in “Molecular Photovoltaics,” Acct. Chem. Res., 33, 269 (2000), incorporated herein by reference, yet with whole donor/acceptor interface covered by photo-sensitizing dyes (band gap matched donor or acceptor units), and that both donor and acceptor phases are solids with good orbital overlap. Additionally, with appropriate adjustment of donor and acceptor block sizes and their substituents, energy levels, or with attachment of better photon energy matched sensitizing dyes on the polymer backbone, it is expected that the photon loss, the exciton loss, and the carrier loss (including charge recombination) issues can all be addressed and optimized simultaneously in one such -DBAB-type block copolymer photovoltaic device.

In order to examine or test the feasibility of this block copolymer solar cell design, a specific -DBAB-type of block copolymer was recently synthesized and characterized, and some opto-electronic studies are already in progress, as reported by S. Sun, et al., see, e.g., “Synthesis and Characterization of a Novel -BDBA-Block Copolymer System for Light Harvesting Applications,” in Organic Photovoltaics III, SPIE, 4801, 114-124 (2003), incorporated herein by reference, and “Conjugated Block Copolymers for Opto-Electronic Functions,” Syn. Met. 137, 883-884 (2003), incorporated herein by reference.

As briefly summarized earlier, a -DBAB- or similar analogs, such as -DBA-, -DBABD-, -ABDBA-, etc., as shown schematically in FIG. 5, is essential in this invention. Both donor and acceptor are conjugated chain (or block), with the donor having higher LUMO/HOMO levels than the acceptor block, and with the energy level difference preferably closer to the exciton binding energy corresponding to the type of conjugated units, e.g., 0.4-0.5 eV for PPV type conjugated polymers. Additionally, the LUMO/HOMO optical gap of both donor and acceptor preferably match the photon energy, e.g., 1.3-2.0 eV in case of solar cell applications. Typically, the HOMO/LUMO levels in organic materials can be adjusted via electro-active group substitutions on the conjugated chain. The LUMO/HOMO values may be estimated using certain known theoretical models and calculation methods as described by J. L. Bredas, et al., in “Chain-Length Dependence of Electronic and Electrochemical Properties of Conjugated Systems: Polyacetylene, Polyphenylene, Polythiophene, and Polypyrrole,” J. Am. Chem., 105, 6555-6559 (1983), incorporated herein by reference, or may be experimentally measured after the materials are synthesized as elaborated below. The size (or main chain length) of the donor or acceptor conjugated chain should be no shorter than the typical size of an intra-chain exciton corresponding to the type of conjugated units, and no longer than the average exciton diffusion length corresponding to the type of conjugated units. In PPV for example, the conjugated chain size is preferably between 2-10 nm (corresponding to 3-15 phenylene-vinylene repeating units). The bridge chain should be such that, after coupling with a donor on one end and an acceptor on the other end, at least three consecutive single (σ) bonds exist on the bridge chain, and the LUMO level of the bridge is higher than the LUMO of both the donor and acceptor chains, and that the HOMO level of the bridge is lower than the HOMO of both the donor and acceptor chains, as shown in FIG. 6. In general, most aliphatic chains containing only single (σ) bonds can satisfy this LUMO/HOMO energy level requirement. A minimum of three consecutive single bonds would not only ensure a non-conjugated large band gap energy barrier between the two conjugated chains, it also enables the bridge a 180° bending capacity from the “primary structure” shape, as shown in FIG. 5 to the vertically stacked “secondary structure,” as shown in FIG. 7.

While a number of ways or strategies may be used to synthesize the target -DBAB-type of block copolymers, at least one strategy or method follows: A two-end functionalized donor chain, a two-end functionalized acceptor chain, and a two-end functionalized bridge chain are synthesized first and separately, and the end functional group of each chain should be such that both donor and acceptor chains will react and couple with the bridge chain, yet the donor chain will not react with the acceptor chain and vice-versa, and each chain will not react with itself. Once individual chains are prepared, then either the donor or the acceptor chain is added by drops to an excess amount of the bridge chain, such that predominantly -BDB- or -BAB-units are formed first. Then -BDB- can react with acceptor (A) chain in a 1:1 molar ratio, or the -BAB-chain can react with the donor (D) chain in a 1:1 molar ratio. Thus, the final conjugated units of -DBAB- can be synthesized. Such a synthetic protocol has already been demonstrated experimentally by S. Sun, et al., in “Synthesis and Characterization of a Novel -BDBA-Block Copolymer System for Light Harvesting Applications,” in Organic Photovoltaics III, SPIE Proc., 4801, 114-124 (2003), incorporated herein by reference, and as shown in FIG. 10.

Once the donor (D) and acceptor (A) chains are synthesized, their LUMO/HOMO levels should be measured or determined first before proceeding further. The experimental determination of LUMO/HOMO levels of organic materials may use standard literature procedures, for instance, those described by S. Janietz, et al., in “Electrochemical determination of the ionization potential and electron affinity of poly9,9-dioctylfluorene,” Appl. Phy. Lett., 73, 2453-2455 (1998), incorporated herein by reference. Once the measured LUMO/HOMO values indeed satisfy or meet the criteria set forth in this invention, then final -DBAB-type block copolymer synthesis can proceed according to the protocol described above.

Photovoltaic devices (cells) can be fabricated as follows: For the first device, shown in FIG. 9, the photovoltaic block copolymer samples first need to be dissolved in an appropriate solvent that can be conveniently dried. Then the polymer solution needs to be filtered (preferably using a 0.2 micron pore size PTFE filter, i.e., Teflon®) to remove large insoluble particles. The sample solution can then be either spin coated or simply drop dried onto a pre-cleaned India Tin Oxide (ITO) conducting glass slide. The thickness of the thin film can be controlled in a number of ways, such as concentration of the solution, the spin coating speed (in case of spin coating), etc. The solvent residue can be removed by heating, exposure to a vacuum, or a combination of both, such as in a heated vacuum oven. The film thickness can be measured using a number of methods or tools; one such method is to use a commercially available profilometer. The thickness of the film needs to be controlled; if the film is too thick, photo-generated carrier loss would become larger, particularly for amorphous thin films without any molecular self-assembly. However, if the film is too thin, photon loss would be more severe as absorption is best when the film thickness is close to the wavelength of the photon. For solar energy applications, since the maximum solar photon flux is between 600-900 nm, an ideal thickness should be in this range. Yet in reality, due to the carrier loss problem, a balanced approach has to be applied; therefore, a 100-200 nm thick photovoltaic polymer layer is desirable and is typically applied in most organic PV cells fabricated so far.

Block copolymer supramolecular structure or morphology, defined as “secondary” and “tertiary” structures in this invention, is very critical for exciton diffusion, charge separation, and, particularly, carrier transportation. For instance, Schwartz, et al., in “Control of Energy Transfer in Oriented Conjugated Polymer-Mesoporous Silica Composites,” Science, 288, 652 (2000), incorporated herein by reference, demonstrated that the energy transfer (exciton diffusion) in a PPV system is more effective between the parallel aligned conjugated chains (inter-chain) than within the chain (intra-chain); however, charge carrier transportation is more effective or faster along the conjugated chain (intra-chain) than between the conjugated chains (inter-chain). This is one of the reasons that the example “secondary” and “tertiary” structures in this invention, as shown in FIG. 7-8, are desirable and particularly beneficial for photovoltaic functions, since the excitons generated anywhere can now diffuse, or couple, among the vertically aligned conjugated chains efficiently, and the charged carriers will be able to transport efficiently along the vertically aligned conjugated chain to the respective top and bottom electrodes.

Block copolymer supramolecular structures and morphologies can be manipulated or controlled using a variety of methods. For instance, by using different film forming methods, such as spin coating or drop drying, by changing solvent or concentration, by simple heating after films are dried (also called thermal annealing), and by applying certain external forces such as magnetic, electric, or optical forces. For instance, for the example “secondary structure,” as shown in FIG. 7, since the charges (positive and negative) can move more effectively along the conjugated chain direction, the external magnetic fields, electric fields, or polarized light could be a driving force for the preferential alignment of the rigid conjugated chains to the electric field direction. Recent reports of solar cell performance improvement after certain thermal and electrical post-treatments of a conjugated polymer/fullerene binary thin film may be evidence of such morphology improvements, as reported by F. Padinger, et al., in “Effects of Postproduction Treatment on Plastic Solar Cells,” Adv. Funct. Mater., 13, 1-4 (2003), incorporated herein by reference. Finally, a smaller work function metal electrode, such as aluminum, can be deposited on top of the block copolymer thin film using a standard vacuum thermal evaporation method.

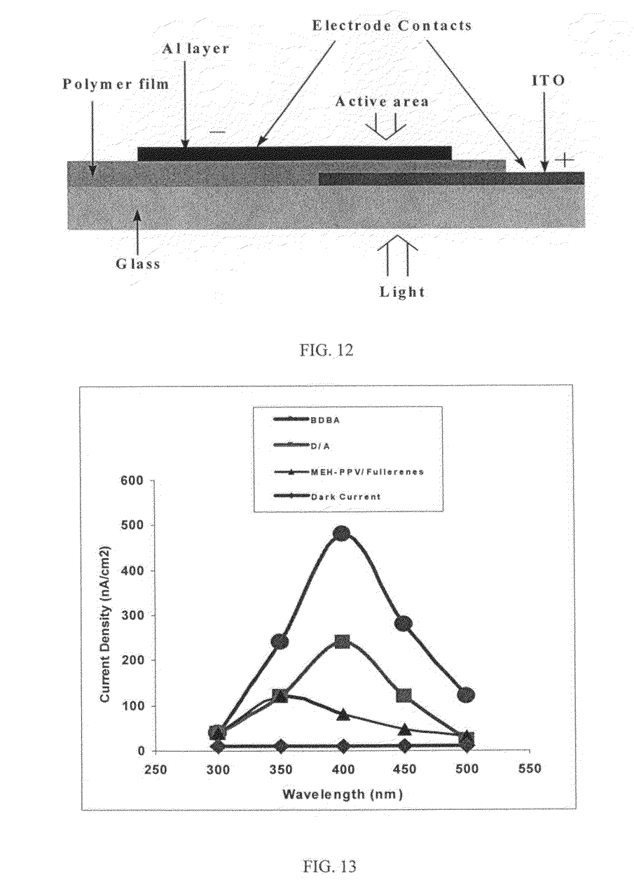

FIG. 12 shows an example of a half-ITO covered photovoltaic device fabricated using the above-mentioned protocol. In this example device fabrication, for instance, a 20×40 mm sized ITO glass slide was immersed halfway into a concentrated sulfuric acid/chromerge cleaning solution for over 8 hours in order to dissolve part of the ITO covered area completely. The purpose of using a partially covered ITO glass is to avoid a possible electrode touching induced short circuit by creating an aluminum electrode contact area where there is no ITO conducting layer right below. Then the whole ITO glass was submerged briefly into a cleaning solution and was then rinsed with water and ethanol and dried. The ITO slide was then spin coated with approximately 100 nm thick polymer film from a polymer solution. After the film is dried, an aluminum electrode approximately 100 nm thick was vacuum deposited on top of the polymer film. The active area of the photovoltaic cell is defined by the area where aluminum is overlapping with an ITO layer. The active area size may be used to calculate the current density as defined by the total measured current divided by the active area. In this example fabrication, the active area is 10×10 mm.

Once the photovoltaic cell is fabricated, the photo current can be measured by irradiating the cell from the transparent ITO glass slide and, at the same time, measuring the current from the ITO (positive) electrode to the aluminum (negative) electrode using a sensitive current meter. FIG. 13 shows the photocurrent density comparison between several photovoltaic cells fabricated from 100 nm thick film of (1) an RO-PPV (donor) and an SF-PPV-I (acceptor) based -DBAB-block copolymer; and (2) RO-PPV/SF-PPV-I equal molar blend; and (3) commercially available MEH-PPV/fullerenes equal molar blend; and (4) current densities without light radiation (dark current). The light source in this case was a 150 W Xe lamp with a 15×15 mm beam size and a wavelength tunable by a monochromator inside an ISA Fluoromax-3 fluorescence spectrophotometer. The intensity of the light is about 0.01 Sun (one Sun equals 100 mW/cm²).

As FIG. 13 demonstrates, the peak photocurrent of the -DBAB-film was almost doubled in comparison to the simple D/A blend. While the shape of the photocurrent versus wavelength reflects both materials' optical (photon) absorptions as well as light intensity variations, the significant photo current magnitude improvement at the same wavelength is a reflection of either (a) the increased donor/acceptor interface; or (b) better film morphology or smoother carrier transportation pathways; or (c) both factors. Thus, even these very preliminary and not yet optimized tests reveal the superiority of this invention.

Additionally, in order to further enhance charged carrier collections at the electrodes, a thin layer (about 1 nm thick) of lithium fluoride (LiF) can be vacuum deposited between the photoactive materials layer and the (metal) negative electrode, and a thin (50-100 nm) poly(ethylene dioxythiophene)/polystyrene sulfonic acid (PSS/PEDOT) layer can be spin coated (from an aqueous solution) between the ITO glass and the photoactive materials layer. Both LiF and PSS/PEDOT are commercially available and have been known to improve the carrier collection at the respective electrodes, as shown by C. Brabec, et al., in “Organic Photovoltaics: Concepts and Realization,” Springer, Berlin (2003), incorporated herein by reference.

Finally, a second photovoltaic device can also be fabricated, as shown in FIG. 10. Now a thin donor layer (with thickness less than the average exciton diffusion range, such as 10 nm in case of PPV) is added between the positive electrode and the photovoltaic block copolymer layer, and another thin acceptor layer (also with a thickness less than the average exciton diffusion length) is also added between the photovoltaic block copolymer layer and the negative electrode. Additionally, a 50-100 nm thick PSS/PEDOT layer can also be added between the positive electrode (such as an ITO electrode) and the donor layer, and a 1 nm thick LiF layer can also be added between the acceptor layer and the negative electrode layer (such as an Al electrode) in order to enhance carrier collection at both electrodes. In practice, it is desirable and also critical that, when depositing (either spin coating or drop drying) the second donor layer on top of the first PSS/PEDOT layer, the solvent dissolving the donor will not dissolve the dried PSS/PEDOT layer. The same principle is also applicable for the third block copolymer layer in reference to the second donor layer, and to the fourth acceptor layer in reference to the -DBAB-block layer, and so on. One major advantage of this second photovoltaic cell is that the added donor and acceptor layers would create a desire asymmetry (or photo-induced chemical potential gradient) in the photoactive medium itself (without electrodes), so that even if the two electrodes are the same, asymmetric voltage or current would still be generated by light radiation where the donor layer side would gather more photo-generated holes and therefore constitute the positive electrode side, and the acceptor layer would be rich in photo-generated electrons and therefore constitute a negative electrode side.

This contemplated arrangement may be achieved in a variety of configurations. While there has been described what are believed to be the preferred embodiment of the present invention, those skilled in the art will recognize that other and further changes and modifications may be made thereto without departing from the spirit of the invention, and it is intended to claim all such changes and modifications as fall within the true scope of the invention.

What is claimed is:

1. An organic photovoltaic device; comprising:
a conjugated donor block; and
a conjugated acceptor block joined to the conjugated donor block by a non-conjugated bridge chain.

2. The device described in claim 1 wherein the conjugated donor block has a higher highest occupied molecular orbital and a higher lowest unoccupied molecular orbital than the conjugated acceptor block.

3. The device described in claim 1 wherein the non-conjugated bridge has a highest occupied molecular orbital which is lower than the highest occupied molecular orbital of the conjugated donor block and the conjugated acceptor block and the non-conjugated bridge has a lowest unoccupied molecular orbital which is higher than the lowest unoccupied molecular orbital of the conjugated donor block and the conjugated acceptor block.

4. The device described in claim 1 wherein the non-conjugated bridge is formed such that it is able to bend 180°.

5. The device described in claim 1 further comprising a plurality of conjugated donor blocks and conjugated acceptor blocks which are alternately joined by a plurality of non-conjugated bridges.

6. The device described in claim 1 wherein a plurality of conjugated donor blocks and conjugated acceptor blocks which are alternately joined by a plurality of non-conjugated bridges are formed into hexagonal columns.

7. The device described in claim 6 further comprising:
a positive electrode placed at one end of the columns, and
a negative electrode placed at the end of the columns opposite to the positive electrode.

8. The device described in claim 7 further comprising:
a thin donor layer between the positive electrode and the columns; and
a thin acceptor layer between the negative electrode and the columns.
